(19) United States
(12) Patent Application Publication
(10) Pub. No.: US 2024/0210890 A1
(43) Pub. Date: Jun. 27, 2024

(54) PIEZOELECTRIC DOUBLE RCC PIVOT RESONATOR, IN PARTICULAR FOR HOROLOGICAL ROTARY MOTORS

(71) Applicant: The Swatch Group Research and Development Ltd, Marin (CH)

(72) Inventors: Mohammad Hussein KAHROBAIYAN, Boudevilliers (CH); Yvan FERRI, St-Aubin-sauges (CH); Alexandre DIDIER, Erlach (CH); Lionel PARATTE, Marin-Epagnier (CH); Jean-Jacques BORN, Morges (CH)

(73) Assignee: The Swatch Group Research and Development Ltd, Marin (CH)

(21) Appl. No.: 18/528,940

(22) Filed: Dec. 5, 2023

(30) Foreign Application Priority Data
Dec. 23, 2022 (EP) 22216418.8

(51) Int. Cl. G04C 3/12; H02N 2/10; H02N 2/12

(52) U.S. Cl. CPC G04C 3/12; H02N 2/101; H02N 2/123

(57) ABSTRACT

A piezoelectric resonator for a rotary motor, the resonator including a stationary base and an oscillating mass extending around a longitudinal axis, the oscillating mass having an inertia-block. The resonator includes a flexible blade guide connecting the oscillating mass to the base, so as to be able to cause the oscillating mass to oscillate about a centre of rotation in a balance movement, the flexible guide including a first RCC-type pivot provided with an intermediate moving element, a first pair of flexible blades connecting the base to the intermediate moving element, and a second pair of flexible blades forming a second RCC-type pivot connecting the intermediate moving element to the oscillating mass, the piezoelectric resonator including a first flexible blade connecting the intermediate moving element to the base, the first flexible blade including at least in part a piezoelectric material that can deform the first flexible blade and cause the oscillating mass to oscillate.

### TECHNICAL FIELD OF THE INVENTION

The invention relates to the technical field of piezoelectric resonators, in particular for rotary piezoelectric motors. The invention also relates to the technical field of timepieces provided with such a rotary piezoelectric motor.

### TECHNOLOGICAL BACKGROUND

The electric motors usually used in watchmaking are “Lavet” type rotary motors, which operate on electromagnetic physical principles. Such a motor generally includes a stator provided with coils and a magnetised rotor, which rotates by shifting the phase of the coils.

However, these motors have limited resistance to high magnetic fields. Above a certain magnetic field value, the motor jams. In general, they jam when the magnetic field exceeds 2 mT.

Thus, to avoid this problem, it is necessary to design motors that operate on other physical principles.

For example, there are electrostatic motors with combs, such as the one described in patent CH709512. But combs take up space, and they consume more energy than “Lavet” type motors.

Motors based on the piezoelectric effect have also been developed, for example in patent EP0587031. However, this is limited to actuating a calendar. However, its high power consumption and the risk of premature wear do not allow to drive a second hand, which generally requires the most energy.

### SUMMARY OF THE INVENTION

The purpose of the present invention is to provide a piezoelectric resonator, which can withstand high electromagnetic fields, while maintaining reduced power consumption and volume.

To this end, the invention relates to a piezoelectric resonator, in particular for a rotary piezoelectric motor of a timepiece, the piezoelectric resonator comprising a stationary base and an oscillating mass extending around a longitudinal axis, the oscillating mass being provided with at least one inertia-block, preferably two inertia-blocks arranged in opposite positions.

The invention is remarkable in that the piezoelectric resonator comprises a flexible blade guide connecting the oscillating mass to the base, so as to be able to cause the oscillating mass to oscillate about a centre of rotation in a balance movement, the flexible guide comprising a first RCC-type pivot provided with an intermediate moving element, a first pair of flexible blades connecting the base to the intermediate moving element, and a second pair of flexible blades forming a second RCC-type pivot connecting the intermediate moving element to the oscillating mass, the piezoelectric resonator comprising a first flexible blade connecting the intermediate moving element to the base, the first flexible blade including at least in part a piezoelectric material that can be electrically actuated to deform the first flexible blade and cause the oscillating mass to oscillate.

A resonator with such a configuration can provide movement efficiently. Indeed, by actuating the piezoelectric material of the flexible blade(s), they bend so that the oscillating mass oscillates by pivoting on itself about a centre of rotation. In this way, the resonator produces an oscillatory movement of the oscillating mass, while consuming little energy, because the actuation of the flexible blade(s) requires less energy.

Furthermore, an RCC-type pivot has the advantage of increasing the oscillatory amplitude of the resonator, thanks to the intermediate moving element and the second pair of flexible blades.

The oscillatory movement can thus be transmitted to other mechanical parts depending on the field of application of the piezoelectric resonator, for example to a toothed wheel of a motor.

According to a particular embodiment of the invention, the first flexible blade is one of the first pair of flexible blades.

According to a particular embodiment of the invention, the centre of rotation is arranged substantially on the intermediate moving element.

According to a particular embodiment of the invention, the first pair of flexible blades includes a second flexible blade connecting the base to the intermediate moving element, the second flexible blade including at least in part a piezoelectric material that can be electrically actuated to deform the second flexible blade and cause the oscillating mass to oscillate.

According to a particular embodiment of the invention, the first flexible blade and the second flexible blade form an angle comprised between 30° and 150°, preferably between 60° and 130°, or even between 90° and 120°.

According to a particular embodiment of the invention, the first flexible blade and the second flexible blade are uncrossed and extend from the intermediate moving element to eccentric portions of the base.

According to a particular embodiment of the invention, the first flexible blade is an additional blade different from the flexible blades of the first pair of flexible blades.

According to a particular embodiment of the invention, the first pair of flexible blades includes a second flexible blade and a third flexible blade connecting the base to the intermediate moving element.

According to a particular embodiment of the invention, the second flexible blade and the third flexible blade are uncrossed and extend from the intermediate moving element to eccentric portions of the base.

According to a particular embodiment of the invention, the second flexible blade and the third flexible blade form an angle comprised between 30° and 150°, preferably between 60° and 130°, or even between 90° and 120°.

According to a particular embodiment of the invention, the second pair of flexible blades includes two flexible blades extending from the intermediate moving element to the oscillating mass.

According to a particular embodiment of the invention, the two flexible blades of the second pair of flexible blades form an angle comprised between 30° and 150°, preferably between 60° and 130°, or even between 90° and 120°.

According to a particular embodiment of the invention, the two flexible blades of the second pair of flexible blades are arranged axially symmetrically with respect to each other.

According to a particular embodiment of the invention, the resonator is arranged substantially in the same plane.

According to a particular embodiment of the invention, the resonator is configured to cause the oscillating mass to oscillate at the natural frequency of the resonator.

According to a particular embodiment of the invention, the resonator includes, preferably mainly, a non-magnetic monocrystalline or polycrystalline material with low conductivity, such as silicon, glass, ceramic or a metal, is obtained, for example, by a MEMS-type photo-lithographic micromachining method.

According to a particular embodiment of the invention, the flexible guide is made in one piece.

The invention also relates to a piezoelectric motor, in particular for a display device of a timepiece, comprising such a piezoelectric resonator.

According to a particular embodiment of the invention, the piezoelectric motor comprises at least one pawl, preferably two pawls, and a moving wheel, the pawl being mounted on the oscillating mass of the piezoelectric resonator so as to rotate the moving wheel in a first direction when the oscillating mass performs its oscillations.

The invention further relates to a timepiece including a horological movement comprising a gear transmission configured to rotate at least one hand, and comprising such a piezoelectric motor arranged to actuate the gear transmission.

### BRIEF DESCRIPTION OF THE FIGURES

Other features and advantages will be clear from the description which follows, in an indicative and non-limiting manner, with reference to the appended drawings, wherein:

FIG. 1 schematically shows a top view of a first embodiment of a piezoelectric resonator, in particular for a rotary motor, according to the invention,

FIG. 2 schematically shows a top view of a second embodiment of a piezoelectric resonator, in particular for a rotary motor, according to the invention,

FIG. 3 schematically shows a top view of a third embodiment of a piezoelectric resonator, in particular for a rotary motor, according to the invention,

FIG. 4 schematically shows a top view of a fourth embodiment of a piezoelectric resonator, in particular for a rotary motor, according to the invention, and

FIG. 5 schematically shows a top view of an embodiment of a piezoelectric motor comprising a piezoelectric resonator according to the invention.

### DETAILED DESCRIPTION OF THE INVENTION

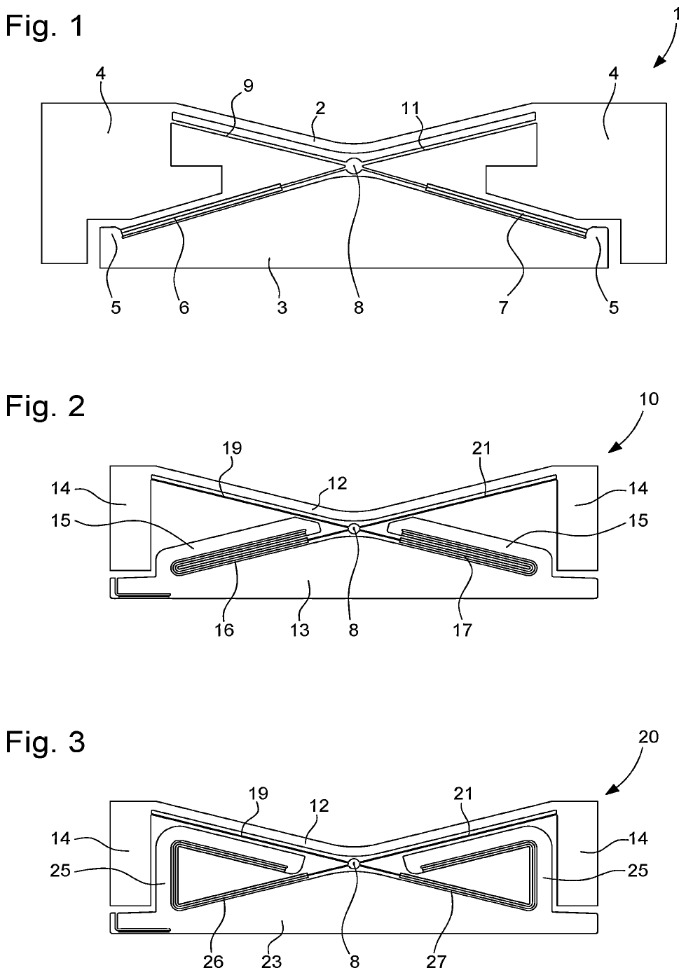

FIGS. 1 to 6 show different embodiments of a piezoelectric resonator, in particular used in a rotary motor. In particular, the motor can be used in a timepiece to actuate a display device comprising hands arranged on a dial. The piezoelectric resonator 1, 10, 20, 30, 40 preferably extends substantially in a plane.

In FIG. 1, the first embodiment of the piezoelectric resonator comprises a base 3, which here has a substantially triangular, preferably isosceles, shape.

The triangle has a main vertex and two off-centre opposite vertices. The triangle has two equal sides and a base whose length is greater than the height, preferably at least twice as great, or even four or five times as great. The two opposite vertices each include a protrusion 5 extending towards the top of the triangle.

The resonator 1 further comprises an oscillating mass 2. The oscillating mass 2 comprises a main arm at the ends of which are arranged two inertia-blocks 4. The arm is disposed tangentially to the main vertex of the triangle. The arm is substantially curved in the middle to reserve space for the motor rotor. The oscillating mass 2 and the base 3 are preferably arranged in the same plane.

The resonator comprises a flexible blade guide connecting the oscillating mass 2 to the base 3, so as to be able to cause the oscillating mass 2 to oscillate about a centre of rotation in a balance movement.

According to the invention, the flexible guide comprises a first and a second RCC (Remote Centre of Compliance) type pivot. The first pivot comprises an intermediate moving element 8, a first pair of flexible blades 6, 7 connecting the base to the intermediate moving element 8. The second RCC-type pivot comprises a second pair of flexible blades connecting the intermediate moving element to the oscillating mass 2.

The intermediate moving element 8 is a point element, small in size compared with the base 3 and the oscillating mass 2. The point element 8 is, for example, cylindrical in shape. Preferably, the centre of rotation is arranged substantially at the centre of the intermediate moving element 8.

The first pair of flexible blades comprises a first flexible blade 6 connecting the intermediate moving element 8 to the base 3, and a second flexible blade 7 connecting the base 3 to the intermediate moving element 8. Preferably, the first flexible blade 6 and the second flexible blade 7 are substantially straight.

The first flexible blade 6 and the second flexible blade 7 are uncrossed and extend from the intermediate moving element 8 to eccentric portions of the base 3, in this case the protrusions 5. Each flexible blade 6, 7 thus connects a protrusion 5 of the base 3 to the intermediate moving element 8, running along one of the equal sides of the isosceles triangle.

The first flexible blade 6 and the second flexible blade 7 form an angle comprised between 30° and 150°, preferably between 60° and 130°, or even between 90° and 120°. The first flexible blade 6 and the second flexible blade 7 are arranged axially symmetrically with respect to each other.

In this embodiment, the first flexible blade 6 is one of the first pair of flexible blades of the first RCC-type pivot.

The second pair of flexible blades includes a third flexible blade 9, and a fourth flexible blade 11 extending from the intermediate moving element to the oscillating mass 2, more particularly at the top of the inertia-blocks 4, just below the arm.

Thus, the blades of the first pair of flexible blades and the second pair of flexible blades extend on opposite sides to the blades of the first pair.

Preferably, the first flexible blade 6 and the fourth flexible blade 11 are symmetrical with respect to the intermediate element 8. Preferably, the second flexible blade 7 and the third flexible blade 9 are symmetrical with respect to the intermediate element 8.

The first flexible blade 6 and the third flexible blade 9 form an angle comprised between 40° and 90°. The second flexible blade 7 and the fourth flexible blade 11 preferably form an identical angle.

The first flexible blade 6 and the second flexible blade 7 include at least in part a piezoelectric material that can be electrically actuated to deform them and cause the oscillating mass 2 to oscillate.

In this embodiment, the piezoelectric material is arranged on only a portion of each flexible blade 6, 7.

For example, the flexible blades have a layer of piezoelectric material sandwiched between two layers of electrodes. The electrode layers are in turn arranged on top of a monolithic structural support material, for example monocrystalline or polycrystalline silicon, such as quartz, glass, metal, etc.

To actuate the flexible blades 6, 7, the protrusions 5 comprise several electrical contacts connected to the electrode layers to receive an electrical voltage and actuate the piezoelectric layers of the flexible blades.

The piezoelectric layers preferably include a crystalline or polycrystalline material, for example solid ceramic (for sodium potassium niobate) or PZT (for lead titanium zirconate) type ceramic, with the flexible blades 6, 7 having a thickness that allows them to be deformed.

Thus, by electrically activating the layers of piezoelectric material, the flexible blades 6, 7 alternately deform laterally towards the centre and outwards. The activation is produced with an alternating voltage.

By choosing to actuate the two flexible blades 6, 7 in phase opposition, by reversing the polarity of one blade to the other, the intermediate element 8 performs small oscillations, which are transmitted to the oscillating mass 2 via the flexible blades 9, 11 of the second pair.

Thus, the oscillating mass 2 oscillates about a centre of rotation corresponding to the point of intersection of the two flexible blades, in this case at the intermediate element 8. The two inertia-blocks 4 move laterally at a certain frequency, preferably at the resonance frequency of the resonator.

A flexible double RCC-type pivot guide increases the amplitude of oscillation of the oscillating mass 2, thanks to the second pair of flexible blades 9, 11.

In the second embodiment of resonator 10 shown in FIG. 2, the base 13 comprises rigid protrusions 15 forming an elongate arm running along each side of the triangle, so as to form two open channels in the base. The first flexible blade 16 and the second flexible blade 17 are U-shaped in each channel. Each flexible blade 16, 17 is attached to the arm at the entrance to the channel.

This configuration means that longer flexible blades can be arranged to increase the amplitude of oscillations.

The rest of the resonator 10 is essentially identical to the first embodiment.

The third embodiment of a piezoelectric resonator 20 shown in FIG. 3 is a variant of the second embodiment.

To further increase the length of the flexible blades of the first pair, the rigid protrusions 25 of the base 23 form a bent arm extending from the triangle of the base 23 towards the oscillating mass 2, and then towards the intermediate element 8 after the bend.

The first flexible blade 26 and the second flexible blade 27 each run along one side of the triangle of the base 23, then along the bent arm of the protrusion, to be attached to the end of the bent arm.

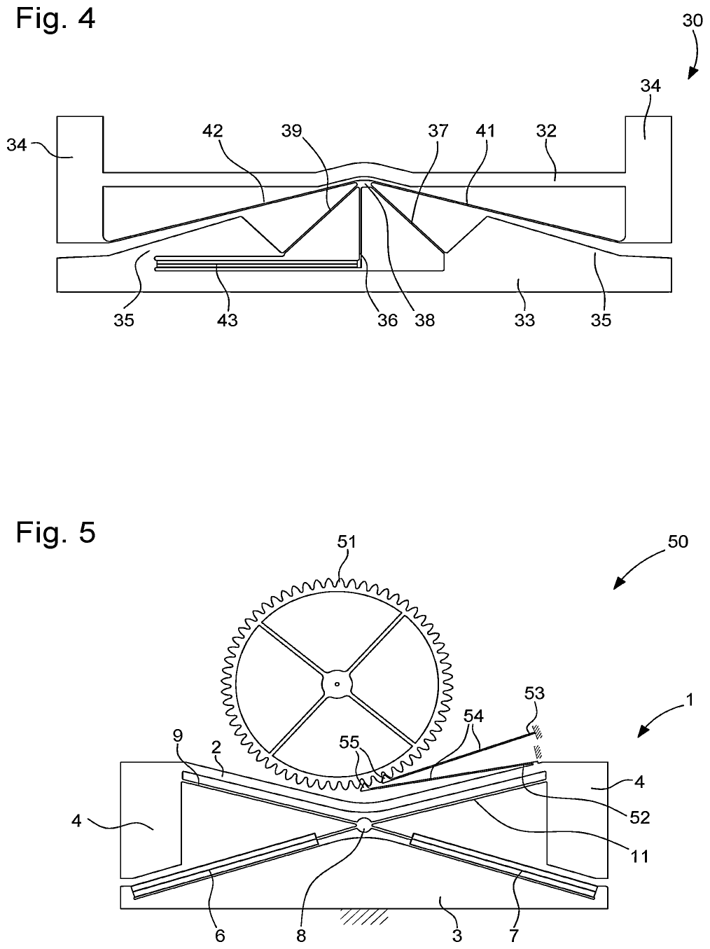

The fourth embodiment shown in FIG. 4 comprises a double RCC pivot flexible guide including an intermediate element 38, a first pair of flexible blades and a second pair of flexible blades without piezoelectric material.

The base 33 has a recessed shape at the centre and two substantially triangular protrusions on either side of the recessed centre.

To actuate the flexible guide, the resonator comprises a first flexible blade arranged between the flexible blades 26, 27 of the first pair of flexible blades. The first flexible blade is L-shaped, of which the first segment 43, which is connected to a triangle of the base 33, comprises the piezoelectric material, and the second segment 44 of the L is connected to the intermediate element 38.

The first flexible blade 36 is an additional blade which is different from the flexible blades of the first and second pairs of flexible blades, and which is used in particular to actuate the flexible guide.

The first pair comprises a second flexible blade 37 and a third flexible blade 39, each of which connects a protrusion 35 to the intermediate element 8. The second flexible blade 37 and the third flexible blade 39 are uncrossed and extend from the intermediate moving element 8 to the base 33. The second flexible blade 37 and the third flexible blade 39 are preferably arranged axially symmetrically with respect to each other.

The second pair comprises a fourth flexible blade 41 and a fifth flexible blade 42. The fourth flexible blade 41 and the fifth flexible blade 42 each connect the intermediate element 8 to the oscillating mass 32, in particular to an inertia-block 34 of the oscillating mass 32. The fourth flexible blade 41 and the fifth flexible blade 42 are uncrossed and extend from the intermediate moving element 8 to the oscillating mass 32. The fourth flexible blade 41 and the fifth flexible blade 42 are preferably arranged axially symmetrically with respect to each other.

The blades of the first and second pairs extend on the same side towards the base 33.

To this end, the fourth flexible blade 41 and the fifth flexible blade 42 are connected to the free end of the inertia-blocks 34 of the oscillating mass 32 in front of the base 33.

The blades 37, 38 of the second pair of flexible blades extend partly between the blades 41, 42 of the first pair of flexible blades.

The fourth flexible blade 41 and the fifth flexible blade 42 form an angle comprised between 90° and 160°.

The second flexible blade 37 and the third flexible blade 39 form an angle comprised between 60° and 100°.

Thanks to the piezoelectric material of the first flexible blade 36, the first flexible blade 36 is alternately deformed to cause oscillation of the intermediate element 8, which is transmitted to the oscillating mass 32.

The resonators 1, 10, 20, 30, according to the methods described above, preferably mainly include a monocrystalline or polycrystalline material, such as silicon, glass, ceramic or a metal.

The resonators 1, 10, 20, 30 are obtained, for example, by photo-lithographic micromachining methods of the MEMS (micro-electro mechanical systems) type. The rigidity, elasticity and machining precision of such materials give the resonators 1, 10, 20, 30 a high resonance quality.

In addition, the non-magnetic and low conductivity features of some of these materials provide excellent resistance to high DC and AC magnetic fields.

Furthermore, the resonators 1, 10, 20, 30 are configured to cause the oscillating mass 2, 12, 22, 32, 42 to oscillate at the natural frequency of the resonator 1, 10, 20, 30. Thus, limiting the energy consumption of the resonator, in particular by increasing the angular travel of the oscillating mass.

FIG. 5 shows an example of a rotary piezoelectric motor 50, in particular for a display device on a timepiece.

In particular, the piezoelectric motor 50 can be used in a timepiece to actuate a display device, such as hands arranged on a dial. The piezoelectric motor 50 is configured so that it can rotate and actuate a mechanical gear transmission of the display device.

The piezoelectric motor 50 comprises a piezoelectric resonator according to the invention, in this case the piezoelectric resonator 1 of the first embodiment shown in FIG. 1. The other piezoelectric resonator embodiments can also be used without changing the operation of the piezoelectric motor 50. The piezoelectric resonator 1 is assembled to a plate by its base 3.

The piezoelectric motor 50 further comprises a toothed moving wheel 51 and two pawls 52, 53 configured to rotate the moving wheel 51 in a single direction. The moving wheel 51 comprises peripheral toothing, which is preferably asymmetrical, which defines the direction of rotation. The moving wheel 50 is connected to a gear provided with the hands of the display device.

The first pawl 52 has the function of rotating the moving wheel 51 in a first direction, for example counter-clockwise direction, while the second pawl 53 holds the moving wheel 51 when the first pawl 52 coils on the next tooth of the rotor 51.

Each pawl 52, 53 includes a flexible blade 54 with a tooth 55, which is preferably asymmetrical, at its end.

The rotation of the moving wheel 51 is generated by movement of the first pawl 52. The first pawl 52 is mounted on the oscillating mass 32 of the piezoelectric resonator 30. Thus, when the resonator oscillates, the first pawl 52 also oscillates, so that it pushes or pulls the toothed moving wheel 51 in a first direction depending on the positioning of the piezoelectric resonator relative to the moving wheel 51.

The second pawl 53 is either assembled on the plate, a plate bridge, or directly on the base 30 to limit the positioning error due to the sequence of assembly tolerances. Its function is to prevent the toothed wheel from rotating in the direction opposite to the first direction. The tooth 55 of the second pawl 53 is configured to cooperate with the asymmetrical toothing, so as to allow the moving wheel 51 to rotate in the first direction, and to block it in the opposite direction.

To this end, the flexible arms 54 of the pawls 52, 53 are in a relaxed straight position, when the tooth 55 is inserted in the toothing of the toothed wheel 51, whereas they are coiled and bent, when pushed outwards by the toothing, when the toothed wheel 51 rotates in the first direction.

In the case of a watch, the resonance frequency or natural frequency of the motor 1 is adapted to the frequency of the quartz, which is used to regulate the rate of the movement. An excitation frequency is chosen that corresponds to a sub-multiple of the quartz frequency, which is generally 32764 Hz. For example, a frequency of 128 Hz or 256 Hz is chosen. The frequency of the motor 1 is preferably adjusted and tuned to the excitation frequency so that its oscillation amplitude does not fall below 90-95% of the maximum amplitude.

Optionally, the second pawl 53 can be configured to act as a pitch sensor, in order to determine the distance or speed of rotation of the moving wheel 51. To this end, the flexible arm 54 of the second pawl 53 is provided with a piezoelectric material connected to a counting unit. Each time the second pawl 53 is bent, the counting unit registers a rotation of the moving wheel 51 by one tooth.

It will be understood that various modifications and/or improvements and/or combinations obvious to the person skilled in the art may be made to the various embodiments of the invention set out above without departing from the scope of the invention defined by the appended claims.

1. A piezoelectric resonator for a rotary piezoelectric motor, the resonator comprising a stationary base and an oscillating mass being provided with at least one inertia-block arranged in opposite positions, wherein the resonator comprises a flexible blade guide connecting the oscillating mass to the base, so as to be able to cause the oscillating mass to oscillate about a centre of rotation in a balance movement, the flexible guide comprising a first RCC-type pivot provided with an intermediate moving element and a first pair of flexible blades connecting the base to the intermediate moving element, and a second pair of flexible blades forming a second RCC-type pivot connecting the intermediate moving element to the oscillating mass, the piezoelectric resonator comprising a first flexible blade connecting the intermediate moving element to the base, the first flexible blade including at least in part a piezoelectric material that can be electrically actuated to deform the first flexible blade and cause the oscillating mass to oscillate.

2. The piezoelectric resonator according to claim 1, wherein the centre of rotation is arranged substantially at the centre of the intermediate moving element.

3. The piezoelectric resonator according to claim 1, wherein the first flexible blade is one of the first pair of flexible blades.

4. The piezoelectric resonator according to claim 3, wherein the first pair of flexible blades comprises a second flexible blade connecting the base to the intermediate moving element, the second flexible blade including at least in part a piezoelectric material that can be electrically actuated to deform the second flexible blade and cause the oscillating mass to oscillate.

5. The piezoelectric resonator according to claim 4, wherein the first flexible blade and the second flexible blade form an angle comprised between 30° and 150°.

6. The piezoelectric resonator according to claim 5, wherein the first flexible blade and the second flexible blade are uncrossed and extend from the intermediate moving element to eccentric portions of the base.

7. The piezoelectric resonator according to claim 3, wherein the first flexible blade is an additional blade different from the flexible blades of the first pair of flexible blades.

8. The piezoelectric resonator according to claim 7, wherein the first pair of flexible blades includes a second flexible blade and a third flexible blade connecting the base to the intermediate moving element.

9. The piezoelectric resonator according to claim 8, wherein the second flexible blade and the third flexible blade are uncrossed and extend from the intermediate moving element to eccentric portions of the base.

10. The piezoelectric resonator according to claim 8, wherein the second flexible blade and the third flexible blade form an angle comprised between 30° and 150°.

11. The piezoelectric resonator according to claim 1, wherein the second pair of flexible blades includes two flexible blades extending from the intermediate moving element to the oscillating mass.

12. The piezoelectric resonator according to claim 11, wherein the two flexible blades of the second pair of flexible blades form an angle comprised between 30° and 150°.

13. The piezoelectric resonator according to claim 12, wherein the two flexible blades of the second pair of flexible blades are arranged axially symmetrically with respect to each other.

14. The piezoelectric resonator according to claim 1, wherein the resonator is arranged substantially in the same plane.

15. The piezoelectric resonator according to claim 1, wherein the resonator is configured to cause the oscillating mass to oscillate at the natural frequency of the resonator.

16. The piezoelectric resonator according to claim 1, comprising a non-magnetic monocrystalline or polycrystalline material with low conductivity, such as silicon, glass, ceramic or a metal, and obtained, for example, by a MEMS-type photo-lithographic micromachining method.

17. A piezoelectric motor, for a display device of a timepiece, comprising a piezoelectric resonator according to claim 1.

18. The piezoelectric motor according to claim 17, comprising at least one pawl, and a moving wheel, the pawl being mounted on the oscillating mass of the piezoelectric resonator so as to rotate the moving wheel in a first direction when the oscillating mass performs its oscillations.

19. A timepiece including a horological movement comprising a gear transmission configured to rotate at least one hand, wherein the timepiece comprises a piezoelectric resonator or a piezoelectric motor according to claim 1, the piezoelectric motor being arranged to actuate the gear transmission.
